(19) United States
(12) Patent Application Publication
(10) Pub. No.: US 2025/0334634 A1
(43) Pub. Date: Oct. 30, 2025

(54) COMMUNICATION CIRCUITS WITH REDUCED KICKBACK NOISE OF EYE OPENING MONITOR

(71) Applicant: RAMSCHIP, INC., Seongnam-si (KR)

(72) Inventors: Jaegan KO, Seongnam-si (KR); Jeonghyu YANG, Seongnam-si (KR); Bokyung KIM, Seoul (KR); Bongjoon LEE, Seongnam-si (KR)

(21) Appl. No.: 18/760,241

(22) Filed: Jul. 1, 2024

(30) Foreign Application Priority Data
Apr. 30, 2024 (KR) 10-2024-0058146

(51) Int. Cl. G01R 31/317; G01R 19/165; G01R 31/28

(52) U.S. Cl. CPC G01R 31/31708; G01R 19/16557; G01R 31/2884

(57) ABSTRACT

A communication circuit with reduced kickback noise of an eye opening monitor may include a first sampler, a second sampler, and a preamplifier, wherein when an edge of a sub-clock precedes an edge of a main clock, the first sampler samples a data value by comparing the input signal with a second reference voltage at the edge of the sub-clock, and the second sampler samples a data value by comparing the input signal with a first reference voltage at the edge of the main clock, and when the edge of the sub-clock lags the edge of the main clock, the second sampler samples a data value by comparing the input signal with the second reference voltage at the edge of the sub-clock, and the first sampler samples a data value by comparing the input signal with the first reference voltage at the edge of the main clock.

### BACKGROUND OF THE INVENTION

### Field of the Invention

The present disclosure relates to a communication circuit with reduced kickback noise of an eye opening monitor.

### Background of the Related Art

An eye opening monitor (EOM, or eye monitor) is a tool for evaluating signal quality in a high-speed signal transmission and reception apparatus or high-speed signal transmission and reception system. That is, the performance of a communication channel may be quantitatively measured using an EOM, and the reliability of a communication system and data may be improved based on data measured by utilizing the EOM. The EOM may be mainly divided into 1-D (checking signal quality in a time or voltage axis) and 2-D (checking signal quality in both time and voltage axes) types, and selected as a type that matches the kind and requirements of an application.

In an interface circuit that operates at high speed, the eye of a signal is essential for determining channel influence, system debugging, and signal integrity, and in a process of performing EOM, kickback generated by a preceding clock may enter an input of another sampler, which may cause a problem in which an output value of the sampler changes, and thus a measure against the problem is required. Referring to FIG. 7, when a comparator operates, kickback occurs at an input signal terminal according to a clock signal. For eye opening monitoring, two or more comparators must be used, and the operation clock timings of respective comparators are different, and as a result, kickback caused by a comparator that operates first may affect another comparator.

The above-described background technology is technical information possessed by the inventor for deriving the present disclosure or acquired in the process of deriving the present disclosure, and cannot necessarily be said to be known technology disclosed to the general public prior to filing the application for the present disclosure.

### CITATION LIST

### Patent Literature

(Patent Document 1) KR 10-2275636

### SUMMARY OF THE INVENTION

One aspect of the present disclosure may provide a communication circuit capable of eye diagram monitoring while reducing kickback noise.

Another aspect of the present disclosure may reduce power consumption on a reception side while reducing kickback noise.

In order to achieve the foregoing objective, a communication circuit with reduced kickback noise of an eye opening monitor according to an embodiment of the present disclosure is contrived, the communication circuit that is configured to measure information for generating an eye diagram with respect to at least one point of a transmission apparatus or reception apparatus may include a first sampler, a second sampler, and a preamplifier, wherein first and second output terminals of the preamplifier are connected to first and second input terminals of the first sampler, respectively, an input signal is applied to first input terminals of the preamplifier and the second sampler, respectively, and when an edge of a sub-clock precedes an edge of a main clock, the first sampler samples a data value by comparing the input signal with a second reference voltage at the edge of the sub-clock, and the second sampler samples a data value by comparing the input signal with a first reference voltage at the edge of the main clock, and when the edge of the sub-clock lags the edge of the main clock, the second sampler samples a data value by comparing the input signal with the second reference voltage at the edge of the sub-clock, and the first sampler samples a data value by comparing the input signal with the first reference voltage at the edge of the main clock.

The communication circuit may further include a first multiplexer whose output terminal is connected to a second input terminal of the preamplifier; a second multiplexer whose output terminal is connected to a second input terminal of the second sampler; a third multiplexer whose output terminal is connected to a clock input terminal of the first sampler; a fourth multiplexer whose output terminal is connected to a clock input terminal of the second sampler; a reference voltage generator that generates the second reference voltage; and a phase interpolator that generates the sub-clock, wherein the first reference voltage is applied to first input terminals of the first multiplexer and the second multiplexer, respectively, the second reference voltage is applied to second input terminals of the first multiplexer and the second multiplexer, respectively, the main clock is applied to first input terminals of the third multiplexer and the fourth multiplexer, respectively, and the sub-clock is applied to second input terminals of the third multiplexer and the fourth multiplexer, respectively.

Furthermore, the communication circuit may further include retimers that adjust timings of an output value of the first sampler and an output value of the second sampler to output the adjusted timings; and an XOR gate so as to compare the output values of the retimers.

Furthermore, the communication circuit may further include an XOR gate that compares an output value of the first sampler with an output value of the second sampler; and a flip-flop connected to an output terminal of the XOR gate, wherein the flip-flop performs a function of selecting valid data excluding garbage data from the output value of the XOR gate, the garbage data being generated due to a timing difference between the output value of the first sampler and the output value of the second sampler.

Furthermore, the communication circuit may further include a post-processing means to remove a time axis error of the eye diagram caused by a delay time of the preamplifier through post-processing.

According to an embodiment of the present disclosure, it may be possible to provide a useful effect capable of performing eye diagram monitoring while reducing kickback noise in a high-speed communication environment.

In addition, according to another embodiment of the present disclosure, power consumption on a reception side may be reduced while reducing kickback noise.

### BRIEF DESCRIPTION OF THE DRAWINGS

FIG. 1 is a diagram for explaining an eye diagram;

FIG. 2 is a diagram schematically illustrating a communication circuit with reduced kickback noise of an eye opening monitor according to an embodiment of the present disclosure;

FIG. 3 is a diagram for explaining a relationship between a main clock and a sub-clock;

FIG. 4 is a diagram for explaining an eye opening monitor circuit of a communication circuit with reduced kickback noise of an eye opening monitor according to an embodiment of the present disclosure;

FIG. 5 is a diagram for explaining an eye opening monitor circuit of a communication circuit with reduced kickback noise of an eye opening monitor according to another embodiment of the present disclosure;

FIG. 6 is a diagram for explaining a signal timing of a communication circuit with reduced kickback noise of an eye opening monitor according to an embodiment of the present disclosure; and

FIG. 7 is a diagram for explaining kickback noises.

### DETAILED DESCRIPTION OF THE PREFERRED EMBODIMENT

Advantages and features of the present disclosure, and methods of accomplishing the same will be clearly understood with reference to the following embodiments described below in detail in conjunction with the accompanying drawings. However, the present disclosure is not limited to the embodiments which will be disclosed below, but may also be implemented in various different forms. The embodiments may be provided to complete the present disclosure and to allow those skilled in the art to fully understand the category of the disclosure throughout the specification, the same reference numerals represent the same elements.

It should be noted that the terms used herein are merely used to describe the embodiments, but not to limit the present disclosure. In this specification, unless clearly used otherwise, expressions in a singular form include a plural form. The term “comprise” and/or “comprising” used in the specification intend to express an element, a step, an operation and/or a device does not exclude the existence or addition of one or more other elements, steps, operations and/or devices.

Although first, second, and the like are used to describe various devices or elements, the devices or elements are not, of course, limited to the terms. The terms are merely used to distinguish one device or element from other devices or elements. Therefore, a first device or element mentioned below may also, of course, be a second device or element within the technical concept of the present disclosure.

Unless otherwise defined, all terms (including technical and scientific terms) used in this specification may be used with meanings that can be commonly understood by those skilled in the art to which the present disclosure pertains. Additionally, terms defined in commonly used dictionaries are not interpreted ideally or excessively unless clearly specifically defined.

Hereinafter, the configuration and operational effects of the present disclosure will be described in more detail with reference to the accompanying drawings.

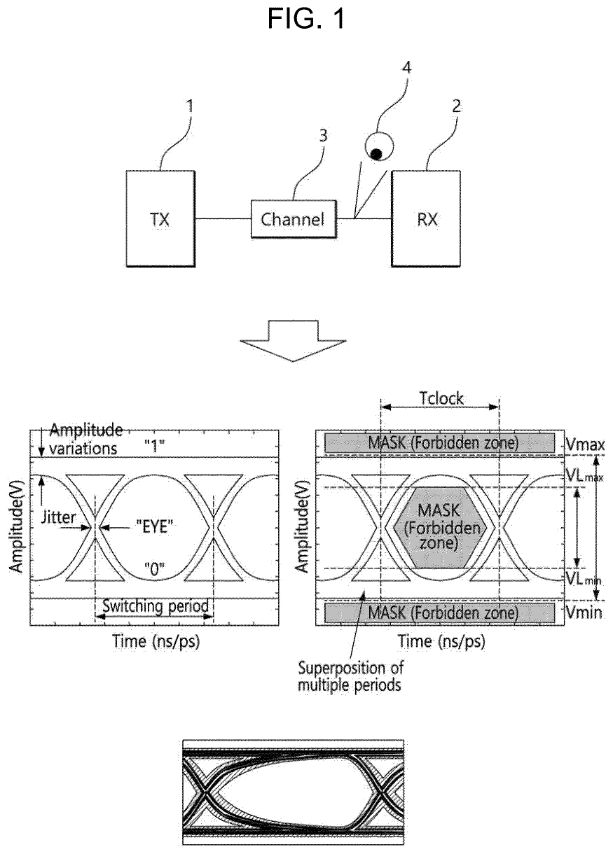

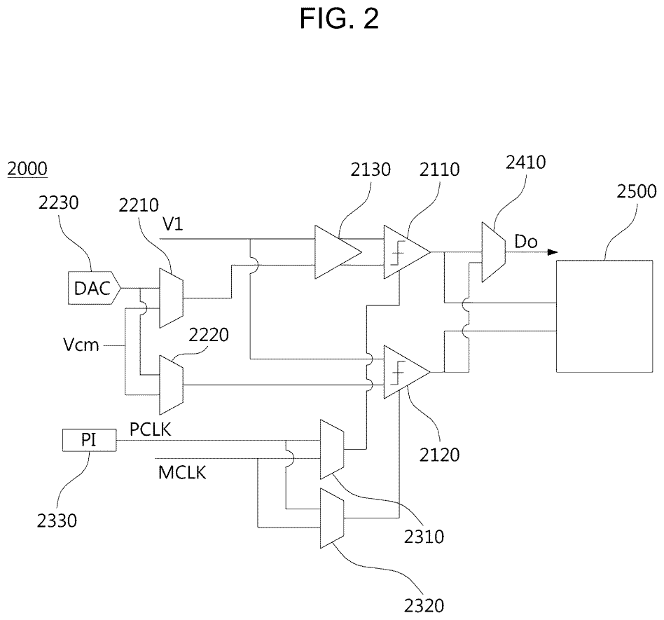

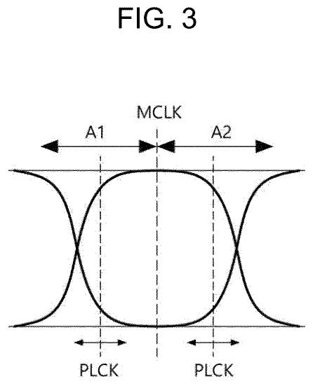

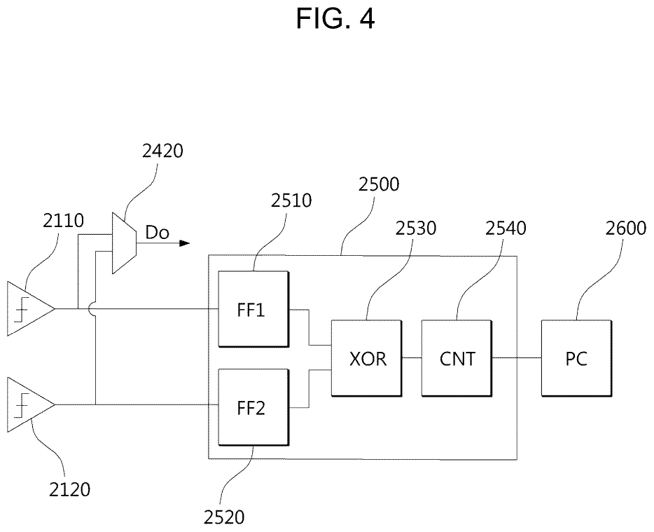

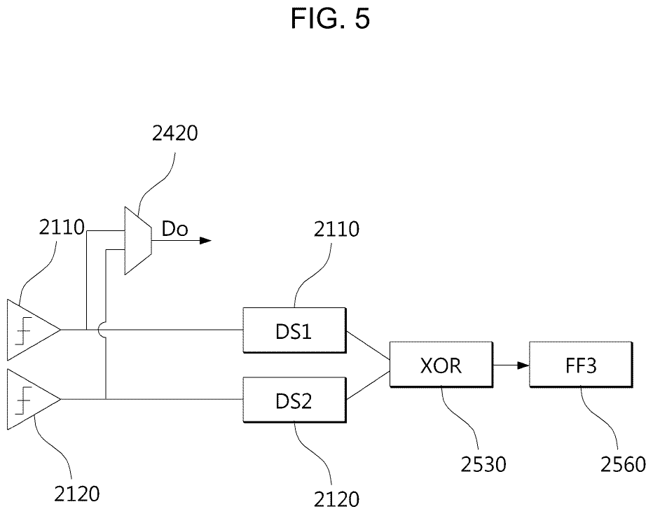

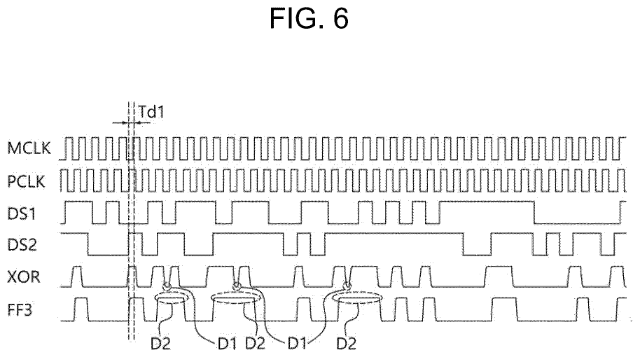

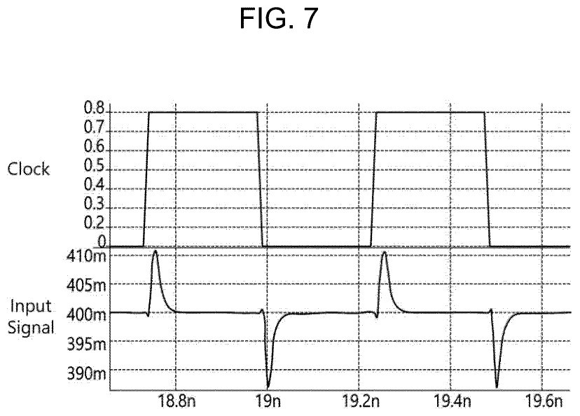

FIG. 1 is a diagram for explaining an eye diagram, FIG. 2 is a diagram schematically illustrating a communication circuit 2000 with reduced kickback noise of an eye opening monitor according to an embodiment of the present disclosure, FIG. 3 is a diagram for explaining a relationship between a main clock MCLK and a sub-clock PCLK, FIG. 4 is a diagram for explaining an eye opening monitor circuit 2500 of a communication circuit 2000 with reduced kickback noise of an eye opening monitor according to an embodiment of the present disclosure, FIG. 5 is a diagram for explaining an eye opening monitor circuit 2500 of a communication circuit 2000 with reduced kickback noise of an eye opening monitor according to another embodiment of the present disclosure, FIG. 6 is a diagram for explaining a signal timing of a communication circuit 2000 with reduced kickback noise of an eye opening monitor according to an embodiment of the present disclosure, and FIG. 7 is a diagram for explaining kickback noises.

Referring to FIG. 1, a transmitter 1 and a receiver 2 may be connected in a wired manner through a communication channel 3. A shape of the eye diagram and terms associated therewith at a point viewed by an eye opening monitor 4 in FIG. 1 are illustrated in FIG. 1.

In one embodiment, the communication circuit 2000 with reduced kickback noise of the eye opening monitor shown in FIG. 2 may include an eye opening monitor circuit 2500, and the eye opening monitor circuit 2500 may include devices for monitoring a waveform with respect to a specific point of a signal reception circuit. The eye opening monitor circuit 2500 may operate by receiving a clock signal, sample a waveform at a point to which the eye opening monitor 4 is connected, and output a result thereof. The eye opening monitor 4 shown in FIG. 1 is disposed on a side of a receiving end to observe a distorted signal passing through the communication channel, but the scope of the present disclosure is not limited thereto. In addition, the eye opening monitor circuit 2500 may receive a signal between an equalizer and a clock-data recovery circuit to monitor an eye opening. As a result of monitoring an eye opening in this manner, an eye diagram may be obtained, and the eye diagram may be utilized inside the receiver, such as being utilized to adjust a setting value of the equalizer. Additionally, eye diagram-related information may be provided to a PC, or the like and utilized for purposes such as post-processing data of an input signal.

A communication circuit 2000 with reduced kickback noise of an eye opening monitor according to an embodiment of the present disclosure includes a first sampler 2110, a second sampler 2120, and a preamplifier 2130. In one embodiment, the communication circuit 2000 with reduced kickback noise of an eye opening monitor may further include first to fourth multiplexers 2210, 2220, 2310, 2320, a reference voltage generator 2230, a phase interpolator 2330, an XOR gate 2530, a counter 2540, and the like.

In one embodiment, the first sampler 2110 and the second sampler 2120 may include comparators, respectively. Here, one of the first sampler 2110 and the second sampler 2120 may output a result of comparing an input signal V1 with a first reference voltage Vcm, and the other one may output a result of comparing the input signal V1 with a second reference voltage. In one embodiment, sampling may be carried out by comparing an input signal with a first reference voltage at an edge of the main clock MCLK, and sampling may be carried out by comparing the input signal with a second reference voltage at an edge of the sub-clock PCLK. In one embodiment, when an edge of the sub-clock PCLK precedes an edge of the main clock MCLK (when an edge of the sub-clock is located in area A1 of FIG. 3), the sub-clock PCLK may be applied to a sampler in which an output terminal of the preamplifier 2130 is connected to an input terminal. In addition, when the edge of the sub-clock PCLK lags the edge of the main clock MCLK (when the edge of the sub-clock is located in area A2 in FIG. 3), the main clock MCLK may be applied to a sampler in which an output terminal of the preamplifier 2130 is connected to an input terminal. In one embodiment, the preamplifier 2130 may receive an input signal and a first reference voltage to output them as they are or amplify and then output them. Meanwhile, the main clock MCLK may refer to a clock used by the receiver to restore data from the input signal. In addition, the sub-clock PCLK may be utilized to search a boundary line of the eye diagram, and may be generated by a phase interpolator (PI), or the like. In the communication circuit 2000 with reduced kickback noise of an eye opening monitor according to an embodiment of the present disclosure, eye opening monitoring may be performed in a manner of carrying out a process of searching a boundary line of an eye diagram while changing a second reference voltage at any one phase, changing the phase when the boundary line is confirmed at the corresponding phase, and then searching the boundary line again. Meanwhile, data sampled by either one of the first sampler 2110 and the second sampler 2120 through receiving the main clock MCLK may be utilized as received data Do. To this end, the first sampler 2110 and the second sampler 2120 may be connected to a fifth multiplexer 2410, 2420, and the fifth multiplexer 2410, 2420 may receive a separate control signal to adjust the output value, and the control signal may be generated to correspond to a preceding-lagging relationship between the main clock MCLK and the sub-clock PCLK to be applied to the fifth multiplexer 2410, 2420.

In one embodiment, first and second output terminals of the preamplifier 2130 may be connected to first and second input terminals of the first sampler 2110, respectively, Furthermore, an input signal may be applied to a first input terminal of the preamplifier 2130, and a first or second reference voltage may be applied to a second input terminal of the preamplifier 2130. To this end, an output terminal of the first multiplexer 2210 may be connected to the second input terminal of the preamplifier 2130, and the first and second reference voltages may be applied to first and second input terminals of the first multiplexer 2210, respectively. Here, the second reference voltage may be generated by the reference voltage generator 2230, and an output terminal of the reference voltage generator 2230 may be connected to the second input terminal of the first multiplexer 2210.

In one embodiment, an input signal may be applied to a first input terminal of the second sampler 2120, and the first or second reference voltage may be applied to a second input terminal of the second sampler 2120. To this end, an output terminal of the second multiplexer 2220 may be connected to the second input terminal of the second sampler 2120, and the first and second reference voltages may be applied to first and second input terminals of the second multiplexer 2220, respectively. Here, the second reference voltage may be generated by the reference voltage generator 2230, and the output terminal of the reference voltage generator 2230 may be connected to the second input terminal of the second multiplexer 2220.

In one embodiment, output terminals of the third multiplexer 2310 and the fourth multiplexer 2320 may be connected to clock input terminals of the first sampler 2110 and the second sampler 2120, respectively. Furthermore, the main clock MCLK may be applied to first input terminals of the third multiplexer 2310 and the fourth multiplexer 2320, respectively, and the sub-clock PCLK may be applied to second input terminals of the third multiplexer 2310 and the fourth multiplexer 2320, respectively.

In one embodiment, when an edge of the sub-clock PCLK precedes an edge of the main clock MCLK, the first sampler 2110 may sample a data value by comparing an input signal with a second reference voltage at the edge of the sub-clock PCLK, and the second sampler 2120 may sample a data value by comparing the input signal with a first reference voltage at the edge of the main clock MCLK.

In one embodiment, when an edge of the sub-clock PCLK lags an edge of the main clock MCLK, the second sampler 2120 may sample a data value by comparing an input signal with a second reference voltage at the edge of the sub-clock PCLK, and the first sampler 2110 may sample a data value by comparing the input signal with a first reference voltage at the edge of the main clock MCLK.

In one embodiment, the first to fourth multiplexers may receive a separate control signal to adjust the output value, and the control signal may be applied to the first to fourth multiplexers to correspond to a preceding-lagging relationship between the main clock MCLK and the sub-clock PCLK.

In one embodiment, an output value of the first sampler 2110 and an output value of the second sampler 2120 may be provided to the eye opening monitor circuit 2500 to be utilized for eye opening monitoring.

Accordingly, a phenomenon in which kickback generated by a preceding clock enters an input of the sampler that utilizes a lagging clock may be blocked by the preamplifier 2130, and as a result, the communication circuit 2000 capable of performing eye diagram monitoring while reducing kickback noise may be implemented. Here, in one embodiment of the present disclosure, a time axis error of the eye diagram caused by a delay time of the preamplifier 2130 may be removed through post-processing. Here, the post-processing process may be performed by a post-processing means such as an eye diagram generation unit 2600.

In one embodiment, after eye opening monitoring is completed, the operation of elements except for those on a path for data reception from among elements for eye opening may be suspended, thereby allowing a low-power operation of a data receiver. That is, according to one embodiment of the present disclosure, kickback noise may be reduced by using the preamplifier 2130, and it is advantageous for reducing power consumption.

In one embodiment, an intermediate value of an input signal may be applied as a first reference voltage. For example, if a minimum value of the input signal is 0 V and a maximum value of the input signal is 100 mV, then 50 mV may be set as the first reference voltage. However, if it is a value between the minimum and maximum values of the input signal, then a value other than the intermediate value may be set as the first reference voltage. However, in this case, the accuracy of determination may be relatively reduced. In one embodiment, the second reference voltage may be set to be offset from the first reference voltage. In another embodiment, the second reference voltage may be set independently of the first reference voltage. In addition, the second reference voltage may be generated by the reference voltage generator 2230, and when a control command signal being output from the control logic block 2570 is applied to the reference voltage generator 2230, the reference voltage generator 2230 may set or change the second reference voltage to correspond to the control command signal. In one embodiment, the reference voltage generator 2230 may be implemented with a digital analog converter (DAC) such as a register DAC. In another embodiment, an additional device may be provided to generate an offset in a differential input transistor for comparison within the sampler (comparator), and a voltage offset may be generated by a method of adjusting a bias current thereof.

Meanwhile, in FIG. 2, the first reference voltage Vcm may be a single-ended signal or a differential signal. In one embodiment, in a case where the first reference voltage Vcm is a single-ended signal, there must be a reference input voltage, and in a case where the first reference voltage Vcm is a differential signal, the reference input voltage may be 0. In the communication circuit 2000 with reduce kickback noise according to an embodiment of the present disclosure, the first reference voltage is not limited to a single-ended signal, and also be a differential signal.

In one embodiment, the communication circuit 2000 with reduced kickback noise may include the eye opening monitor circuit 2500, and the eye opening monitor circuit 2500 may include first and second flip-flops 2510, 2520, a comparison block, a counter 2540, and the like. In one embodiment, the comparison block may be implemented as an XOR gate 2530, but is not limited thereto.

Referring to FIG. 4, the eye opening monitor circuit 2500 may include a first flip-flop 2510, a second flip-flop 2520, an XOR gate 2530, and a counter 2540. The first flip-flop 2510 and the second flip-flop 2520 may be connected to output terminals of the first sampler 2110 and the second sampler 2120, respectively, and respective output terminals of the first flip-flop 2510 and the second flip-flop 2520 may be connected to an input terminal of the XOR gate 2530. The counter 2540 may be connected to an output terminal of the XOR gate 2530. In one embodiment, the XOR gate 2530 may compare two input values to output a comparison result. For instance, the XOR gate 2530 may output 0 when the two input values are the same, and 1 when they are different, and the counter 2540 may count the number of 1s, and a value counted by the counter 2540 in this manner may be provided to the diagram generation unit 2600, or the like. In one embodiment, the eye diagram generation unit 2600 may be implemented with a computer, or the like. In one embodiment, an output of the first sampler 2110 and an output of the second sampler 2120 may be received by the first flip-flop 2510 and the second flip-flop 2520, respectively, and the outputs of the first flip-flop and the second flip-flop may be adjusted by clock signals provided to the first flip-flop and the second flip-flop, thereby solving a problem due to a timing difference between an output value of the first sampler and an output value of the second sampler. From this perspective, the first flip-flop and the second flip-flop may be referred to as retimers that adjust the timings of the output value of the first sampler and the output value of the second sampler. An error occurring due to a timing difference between the output value of the first sampler and the output value of the second sampler may be prevented.

In another embodiment, referring to FIGS. 5 and 6, the respective output terminals of the first sampler 2110 and the second sampler 2120 may be connected to the XOR gate 2530, and a third flip-flop 2560 may be connected to the output terminal of the XOR gate 2530. Here, a clock signal provided to the third flip-flop 2560 may be adjusted so as to prevent an error occurring due to a timing difference between the output value of the first sampler 2110 and the output value of the second sampler 2120. Here, the timing difference between the output value of the first sampler 2110 and the output value of the second sampler 2120 may be caused by a timing difference Td1 between the main clock MCLK and the sub-clock PCLK, and due to this timing difference, garbage data D1 may be generated at the output of the XOR gate 2530, and the third flip-flop 2560 may perform a function of outputting valid data D2 by removing the garbage data DI from a comparison result value being output from the XOR gate 2530.

In an interface circuit that operates at high speed, the eye of a signal is essential for determining channel influence, system debugging, and signal integrity. Since it is difficult to check the eye of a signal from an outside of a chip in a chiplet interface, signal integrity may be tested on-chip using an eye opening monitor (EOM) implemented on the chip. In one embodiment, EOM may be performed in a manner of sampling an input signal with two samplers in a reception circuit and comparing them. Here, one of the two samplers may sample the input signal, and the other sampler may sample the input signal by changing a reference voltage and a clock. At this time, if the results of the two samplers are the same, then a comparison result is 0, and if the results are different, then the comparison result is 1, and a boundary line of the signal may be found by counting the number of 1s. However, since the operation clocks of the two samplers are different, kickback generated by a preceding clock may enter an input terminal of the other sampler, which may cause an output value of the sampler to vary, so it is important to eliminate the effect of the kickback. According to one embodiment of the present disclosure, the influence of the preceding clock may be blocked by the preamplifier 2130 so as to perform eye opening monitoring while reducing kickback noise. In addition, after eye opening monitoring is completed, sampling for eye opening monitoring may be unnecessary, and thus the operation of elements except for those on a path for data reception from among elements for eye opening may be suspended, thereby reducing the power consumption of a data receiver.

The present disclosure has been described with reference to an embodiment illustrated in the accompanying drawings, but the embodiment is merely illustrative, and is not limited to the above-described embodiments, and it should be appreciated by those skilled in the art that various modifications and other embodiments equivalent thereto can be made therefrom. Therefore, the true protective scope of the present disclosure should be determined only by the appended claims.

### DESCRIPTION OF REFERENCE CHARACTERS

2000: Communication circuit with reduced kickback noise of eye opening monitor
2110: First sampler
2120: Second sampler
2130: Preamplifier
2210: First multiplexer
2220: Second multiplexer
2230: Reference voltage generator
2310: Third multiplexer
2320: Fourth multiplexer
2410, 2420: Fifth multiplexer
2330: Phase interpolator
2500: Eye opening monitor circuit
2510: First flip-flop
2520: Second flip-flop
2530: XOR gate
2540: Counter
2560: Third flip-flop
2600: Eye diagram generation unit
MCLK: Main clock
PCLK: Sub-clock

What is claimed is:

1. A communication circuit with reduced kickback noise of an eye opening monitor comprising an eye opening monitor circuit configured to measure information for generating an eye diagram with respect to at least one point of a transmission apparatus or reception apparatus, the communication circuit comprising:
a first sampler (2110), a second sampler (2120), and a preamplifier (2130),
wherein first and second output terminals of the preamplifier are connected to first and second input terminals of the first sampler, respectively,
wherein an input signal V1 is applied to first input terminals of the preamplifier and the second sampler, respectively,
wherein when an edge of a sub-clock PCLK precedes an edge of a main clock MCLK, the first sampler samples a data value by comparing the input signal with a second reference voltage at the edge of the sub-clock, and the second sampler samples a data value by comparing the input signal with a first reference voltage Vcm at the edge of the main clock, and
wherein when the edge of the sub-clock lags the edge of the main clock, the second sampler samples a data value by comparing the input signal with the second reference voltage at the edge of the sub-clock, and the first sampler samples a data value by comparing the input signal with the first reference voltage at the edge of the main clock.

2. The communication circuit of claim 1, further comprising:
a first multiplexer (2210) whose output terminal is connected to a second input terminal of the preamplifier (2130);
a second multiplexer (2220) whose output terminal is connected to a second input terminal of the second sampler (2120);
a third multiplexer (2310) whose output terminal is connected to a clock input terminal of the first sampler (2110);
a fourth multiplexer (2320) whose output terminal is connected to a clock input terminal of the second sampler (2120);
a reference voltage generator (2230) that generates the second reference voltage; and
a phase interpolator (2330) that generates the sub-clock,
wherein the first reference voltage is applied to first input terminals of the first multiplexer and the second multiplexer, respectively,
wherein the second reference voltage is applied to second input terminals of the first multiplexer and the second multiplexer, respectively,
wherein the main clock is applied to first input terminals of the third multiplexer and the fourth multiplexer, respectively, and
wherein the sub-clock is applied to second input terminals of the third multiplexer and the fourth multiplexer, respectively.

3. The communication circuit of claim 1, further comprising:
retimers that adjust timings of an output value of the first sampler and an output value of the second sampler to output the adjusted timings; and
a comparison block that compares the output values of the retimers.

4. The communication circuit of claim 1, further comprising:
a comparison block that compares an output value of the first sampler with an output value of the second sampler; and
a flip-flop connected to an output terminal of the comparison block,
wherein the flip-flop performs a function of selecting valid data excluding garbage data from the output value of the comparison block, and
wherein the garbage data is generated due to a timing difference between the output value of the first sampler and the output value of the second sampler.

5. The communication circuit of claim 1, further comprising:
a post-processing means that removes a time axis error of the eye diagram caused by a delay time of the preamplifier through post-processing.
